(19) United States
(12) Patent Application Publication
(10) Pub. No.: US 2025/0341348 A1
(43) Pub. Date: Nov. 6, 2025

(54) THERMOELECTRIC COOLER INTEGRATION

(71) Applicant: INTERNATIONAL BUSINESS MACHINES CORPORATION, Armonk, NY (US)

(72) Inventors: WuKang Kim, Albany, NY (US); Ruilong Xie, Niskayuna, NY (US); Tao Li, Slingerlands, NY (US); Qianwen Chen, Chappaqua, NY (US); Joshua M. Rubin, Albany, NY (US)

(21) Appl. No.: 18/652,354

(22) Filed: May 1, 2024

(51) Int. Cl. F25B 21/02

(52) U.S. Cl. CPC F25B 21/02

(57) ABSTRACT

A semiconductor device includes transistor devices disposed on a frontside of a dielectric layer. A thermoelectric device is disposed on a backside of the dielectric layer to dissipate heat from the transistor devices. The thermoelectric device includes pillars connected to backside power rails by backside contacts to power the thermoelectric device.

### BACKGROUND

The present invention generally relates to semiconductor devices and processing methods, and more particularly to fabrication of a thermoelectric cooler during a backside integration process.

Semiconductor devices generate heat in accordance with the power dissipation of components across the device. Through silicon vias (TSVs) have been employed as a way to create heat corridors. Placement of TSVs can assist in dissipating heat, but there are limits since TSVs can consume valuable area on the device. Placement of power dissipation structures requires floor planning, either at a chip level or at a routing level. One advantage for TSVs is that hotspots can be targeted, e.g., placed close to a power source.

However, the impact of TSVs is limited. TSVs are only four times as conductive as silicon. This conductivity difference only adds, e.g., about 16% to the effective conductivity of the device. While this provides some benefit, it does not have a large thermal effect. In devices that employ backside power delivery, heat dissipation can be more of a challenge when bulk silicon has a decreased thickness or is completely removed, making heat transfer in local hotspots more difficult to manage. TSVs provide a localized benefit but only in an axis perpendicular to transistors. An oxide liner around TSVs also impedes the lateral thermal energy dissipation.

Therefore, a need exists for integration of a heat dissipation mechanism that can better manage heat transfer in semiconductor devices without area costs.

### SUMMARY

In accordance with an embodiment of the present invention, a semiconductor device includes transistor devices disposed on a frontside of a dielectric layer. A thermoelectric device is disposed on a backside of the dielectric layer to dissipate heat from the transistor devices. The thermoelectric device includes pillars connected to backside power rails by backside contacts to power the thermoelectric device.

In other embodiments, the thermoelectric device can include a cooling plate that spans an area occupied by the transistor devices and other semiconductor components. The pillars can be partially embedded within the cooling plate. The backside power rails can provide supply voltages to the thermoelectric device. The thermoelectric device can be disposed on a first side of a dielectric layer, and heat generating components can be disposed directly on a second side of the dielectric layer opposite the first side. The heat generating components, such as the transistor devices, can include a field effect transistor, and the field effect transistor can include a source/drain region that extends through the dielectric layer. The source/drain region can connect to the backside power rails by the backside contacts. The pillars can include monocrystalline semiconductor material, alloys and/or topological materials.

In accordance with another embodiment of the present invention, a semiconductor device includes a dielectric layer and a component disposed on the dielectric layer. A first doped pillar is disposed on the dielectric layer on a side opposite the component, and a second doped pillar is disposed on the side opposite the component and apart from the first doped pillar. A cooling plate is electrically connected to the first doped pillar and the second doped pillar to provide a thermoelectric device. Contacts are connected to each of the first doped pillar and the second doped pillar. Power rails are connected to the contacts to power the thermoelectric device.

In other embodiments, the cooling plate can span an area occupied by the component. The first doped pillar and the second doped pillar can be partially embedded within the cooling plate. The power rails can be disposed on a backside of the semiconductor device. The component can include a field effect transistor, and the field effect transistor can include a source/drain region that extends through the dielectric layer. The source/drain region can connect to the power rails by the contacts. The first doped pillar and the second doped pillar can be monocrystalline.

In accordance with another embodiment of the present invention, a semiconductor device includes field effect transistors disposed on a dielectric layer and a cooling plate disposed on the dielectric layer on a side opposite the field effect transistors. An N-type monocrystalline pillar is partially embedded within the cooling plate, and a P-type monocrystalline pillar is partially embedded within the cooling plate. A first contact is connected to the N-type monocrystalline pillar, and a second contact is connected to the P-type monocrystalline pillar. A backside positive supply power rail is connected to the first contact, and a backside negative supply power rail connected to the second contact.

In other embodiments, the cooling plate can span an area occupied by the field effect transistors. A field effect transistor can include a source/drain region that extends through the dielectric layer. The source/drain region can include a backside connection. The cooling plate can include a metal.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows cross-sectional views taken at section lines X and Y in an inset layout view depicting dummy gate structures of a wafer for a nanosheet field effect transistor device, in accordance with an embodiment of the present invention;

FIG. 2 shows cross-sectional views taken at section lines X and Y in the inset layout view depicting source/drain regions formed, in accordance with an embodiment of the present invention;

FIG. 3 shows cross-sectional views taken at section lines X and Y in the inset layout view depicting an etch mask formed over a selected source/drain region, in accordance with an embodiment of the present invention;

FIG. 4 shows cross-sectional views taken at section lines X and Y in the inset layout view depicting an etched opening through the selected source/drain region and an underlying dielectric layer, in accordance with an embodiment of the present invention;

FIG. 5 shows cross-sectional views taken at section lines X and Y in the inset layout view depicting the selected source/drain region regrown to extend through the underlying dielectric layer, in accordance with an embodiment of the present invention;

FIG. 6 shows cross-sectional views taken at section lines X and Y in the inset layout view depicting the etched opening filled over the selected source/drain and a gate cut formed in the inset layout view, in accordance with an embodiment of the present invention;

FIG. 7 shows cross-sectional views taken at section lines X and Y in the inset layout view depicting replacement metal gates formed, in accordance with an embodiment of the present invention;

FIG. 8 shows cross-sectional views taken at section lines X and Y in the inset layout view depicting contacts to the source/drain regions formed and a back end of line layer and carrier wafer added, in accordance with an embodiment of the present invention;

FIG. 9 shows cross-sectional views taken at section lines X, Y and Y2 in the inset layout view of FIG. 8 depicting contacts to gate conductors and a substrate removed, in accordance with an embodiment of the present invention;

FIG. 10 shows cross-sectional views taken at section lines X, Y and Y2 in the inset layout view of FIG. 8 depicting an etch stop layer removed and a semiconductor layer patterned to form N-type and P-type monocrystalline pillars, in accordance with an embodiment of the present invention;

FIG. 11 shows cross-sectional views taken at section lines X, Y and Y2 in the inset layout view of FIG. 8 depicting a cooling plate formed, recessed and patterned which partially embeds the N-type and P-type monocrystalline pillars, in accordance with an embodiment of the present invention;

FIG. 12 shows cross-sectional views taken at section lines X, Y and Y2 in the inset layout view of FIG. 8 depicting a dielectric layer and backside contacts formed, in accordance with an embodiment of the present invention;

FIG. 13 shows cross-sectional views taken at section lines X, Y and Y2 in the inset layout view of FIG. 8 depicting backside power rails formed and a backside power distribution network added, in accordance with an embodiment of the present invention; and

FIG. 14 shows a schematic diagram showing operation of a thermoelectric cooling device, in accordance with an embodiment of the present invention.

### DETAILED DESCRIPTION

In accordance with embodiments of the present invention, devices and methods are described which provide a thermoelectric device that can directly connect to a device power grid to enable a cooling effect on a semiconductor device. A thermoelectric device, such as a thermoelectric cooler, can include a cooling metal plate that extends across an area of the semiconductor device. The thermoelectric cooler includes pillars that can create a Peltier effect for actively cooling components of the semiconductor device. The pillars can be formed from any material that can induce the thermoelectric effect. This can include pairs N- and P-type semiconductors (e.g., from monocrystalline material), material alloys and topological materials. The pillars can be connected to supply voltages in a backside power distribution network using the backside contacts. The thermoelectric cooler actively draws heat and carries the heat away from hotspots or components using conduction. This enables a cooling system that can cool chip components, such as, e.g., transistors for memory or logic devices and can provide heat dissipation and therefore performance enhancements as a result of providing an active heat sink for components of the semiconductor device that is directly located at the components being cooled. The effect of having thermoelectric devices can not only solve heat dissipation problems, but also can effectively enhance device performance by reducing thermal carrier transport limitations, which are limited by the Boltzmann limit.

Embodiments of the present invention will be described in terms of an illustrative process involving nanosheet devices. It should be understood that embodiments of the present invention can be employed with any semiconductor device type and processing steps as the need for power dissipation is applicable to semiconductor devices in general. In some embodiments, thermoelectric cooling can be provided on a backside of a semiconductor device. In other embodiments, thermoelectric cooling can be provided on a frontside of the semiconductor device. In still others, thermoelectric cooling can be provided on both the frontside and the backside of the semiconductor device.

In an embodiment, a semiconductor device includes a dielectric layer. The dielectric layer includes an active layer with transistors or other components of one side (e.g., above the dielectric layer). On an opposite side (e.g., below or under the dielectric layer), a thermoelectric cooler is provided. The thermoelectric cooler can include a cooling metal plate and pillars. The cooling plate spans over an area that can include one or more components to be cooled. The pillars can be made by single crystal semiconductor materials and can be doped (e.g., N+ and P+). The pillars can be partially embedded within the cooling plate so that connections are made about the pillar's perimeter. Backside contacts land on the pillars, and source/drain regions of transistors extend through the dielectric layer. The backside contacts can also land on the S/D regions. The thermoelectric cooler can be connected to supply voltage. For example, the thermoelectric cooler can be connected to a positive supply voltage (VDD) power line using an N+ pillar backside contact, and a negative supply voltage (VSS or ground) power line using a P+ pillar backside contact.

In other embodiments, methods for forming a semiconductor device include forming transistors with source/drain (S/D) epitaxial regions (epi regions or epi) extending below a gate structure. After a wafer flip and substrate thinning, pillars are patterned using remaining substrate materials. A cooling metal plate is formed by a deposition process and can include a recess of a thickness of the deposited material. Backside contacts are formed to the S/D epi and also to the pillars, which can include N+ and P+ doped materials. Backside contacts can be wired to backside power lines, such that, e.g., N+ pillars connect to VDD and P+ pillars connect to VSS to form a thermoelectric cooler.

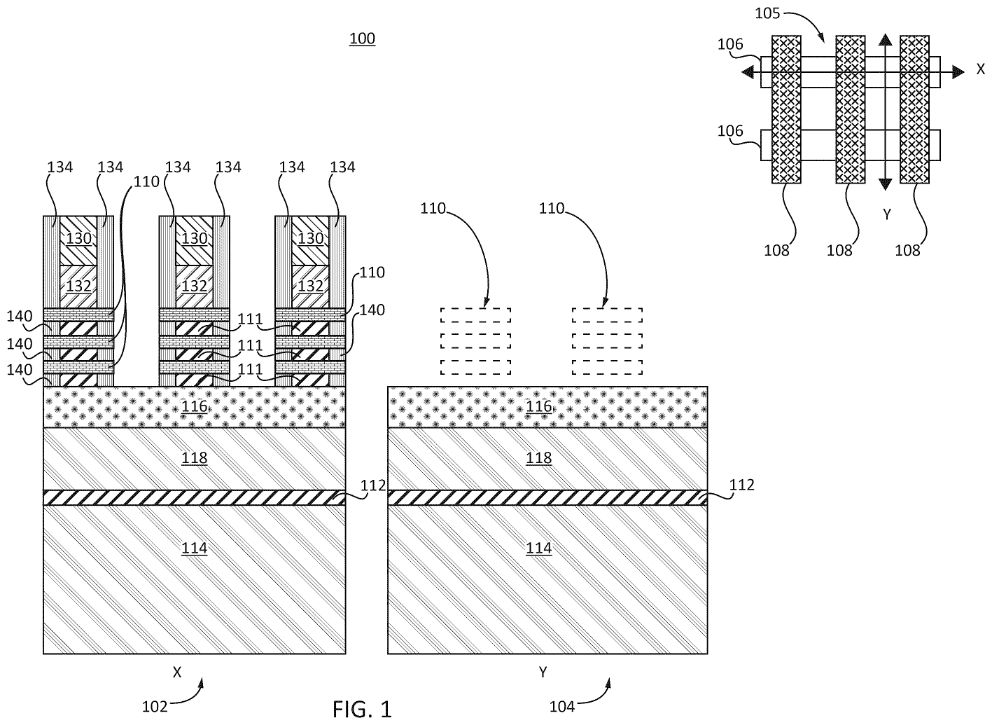

Referring now to the drawings in which like-numerals represent the same or similar elements and initially to FIG. 1, devices and methods for manufacturing field effect transistors (FETs) are shown in accordance with embodiments of the present invention. A wafer 100 includes a substrate 114, which can include one or more layers on which semiconductor processing is performed. FIG. 1 depicts two orthogonal views 102 and 104 of the wafer 100 in an inset layout view 105. View 102 shows a cross-section view taken along source/drain regions 106. View 104 shows a cross-section view taken between and along gate lines 108. Transistor channels 110 are formed at intersections at lines of the source/drain regions 106 and the gate lines 108. Transistor channels 110 are shown in view 104 as projections for reference.

The substrate 114 can include any suitable substrate structure, e.g., a bulk semiconductor, and preferably includes a monocrystalline semiconductor. In one example, the substrate 114 can include a silicon-containing material. Illustrative examples of Si-containing materials suitable for the substrate 114 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 112 is formed on the substrate 114. The etch stop layer 112 can include an epitaxially grown crystal structure. The etch stop layer 112 includes a material that permits the selective etching and removal of the substrate 114 in later steps. In an embodiment, the etch stop layer 112 includes SiGe, although depending on the material of the substrate 114, other materials can be selected, e.g., SiGeC, SiC, etc.

A semiconductor layer 118 is epitaxially grown on the etch stop layer 112. The semiconductor layer 118 can include a same material as the substrate 114, although other semiconductor materials can be employed, e.g., SiGe, SiGeC, SiC, etc. The semiconductor layer 118 includes a monocrystalline structure that can include a perfect crystal or predominantly perfect crystal. The material or portion thereof of the semiconductor layer 118 can be employed for later-formed monolithic pillars.

In illustrative examples described here, a nanosheet stack includes a stack of alternating semiconductor materials. In an embodiment, the nanosheet stack includes nanosheets (NS) that can include semiconductor layers used to form transistor channels 110. The transistor channels 110 can include Si, although other semiconductor materials can be employed. The transistor channels 110 are spaced apart by semiconductor layers 111. The semiconductor layers 111 can include SiGe, although other semiconductor materials can be employed.

The semiconductor layer 118 can include a dielectric layer 116, e.g., a buried oxide (BOX). While dielectric layer 116 is described, other dielectric materials and structures (e.g., shallow trench isolation (STI) regions or STI) can be formed. For example, materials for the dielectric layer 116 can be formed by depositing dielectric material, such as, e.g., SiO₂, SiOₓN_{y}, SiCO or other suitable compounds. Dielectric layer 116 can be deposited using chemical vapor deposition (CVD), although other deposition methods can be employed.

A dummy gate material for dummy gates 132 is blanketed over the wafer 100 followed by a blanket deposition of a hard mask material to later form patterned hard mask 130, e.g., by using photolithographic patterning. The dummy gate material can include a polysilicon, amorphous Si or other selectively removeable material. The hard mask material is patterned to form hard mask 130. The hard mask 130 is employed to etch the dummy gates 132. Then, a deposition process is employed to form spacers 134. Spacers 134 can include an oxide, such as silicon dioxide, although other dielectric materials can be employed.

The hard mask 130 and spacers 134 can be employed as an etch mask to recess the nanosheet (e.g., transistor channels 110 and semiconductor layers 111) to expose the dielectric layer 116. Regions of the nanosheet below the hard mask 130 and spacers 134 are patterned for further processing while the nanosheet is completely removed in other regions (e.g., view 104).

Inner spacers 140 are formed and include a dielectric material. In an embodiment, the inner spacers 140 are formed by being laterally recessed by an etch process followed by a dielectric deposition (e.g., silicon oxide) and etch to form inner spacers 140.

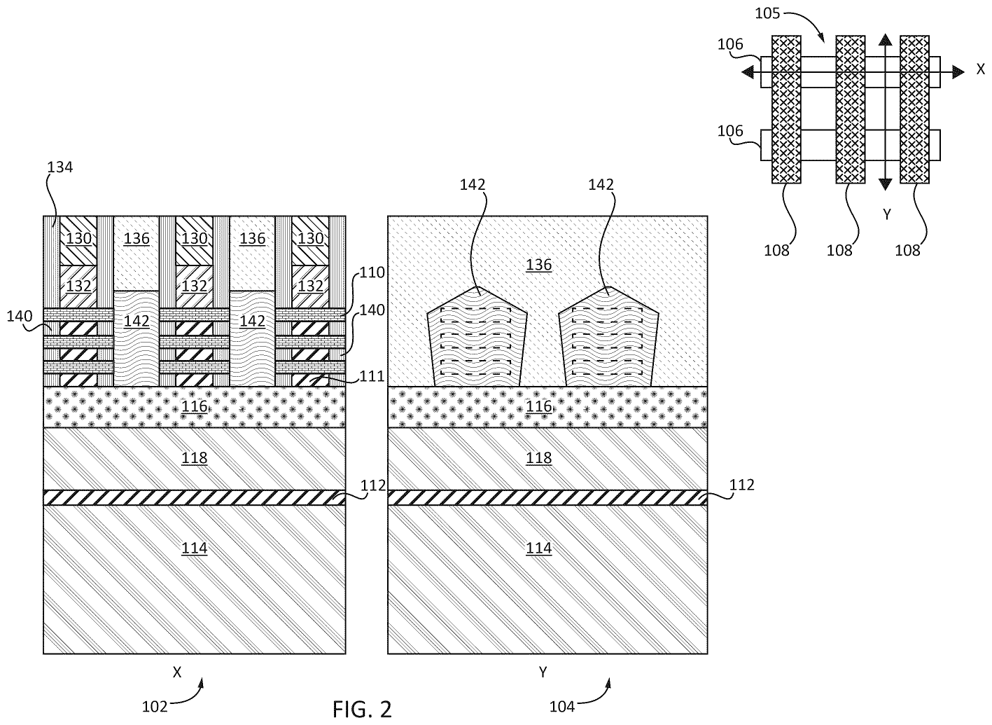

Referring to FIG. 2, an epitaxial growth process is performed to form epitaxial regions for source/drain (S/D) regions 142. Source/drain regions 142 align on opposite sides of transistor channels 110 which are shown in dashed lines since the source/drain regions 142 are blocking the transistor channels 110 from view in view 104. Source/drain regions 142 can include Si or SiGe and include faceted surfaces when epitaxial growth is not confined. In an embodiment, the source/drain regions 142 can be designated as P-type or N-type devices.

The P-type and N-type devices can have materials selected accordingly. For example, if the source/drain regions 142 include N-type devices then the source/drain regions 142 can include Si. In another example, if the source/drain regions 142 include P-type devices then the source/drain regions 142 can include SiGe. The source/drain regions 142 can also be appropriately doped during their formation by epitaxial growth. For example, the source/drain regions 142 can be doped by introducing p dopants (e.g., B, Ga, etc.) during epitaxial formation. Similarly, the source/drain regions 142 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during the processing of the other.

An interlayer dielectric (ILD) 136 can be formed over the wafer 100. The ILD 136 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H.

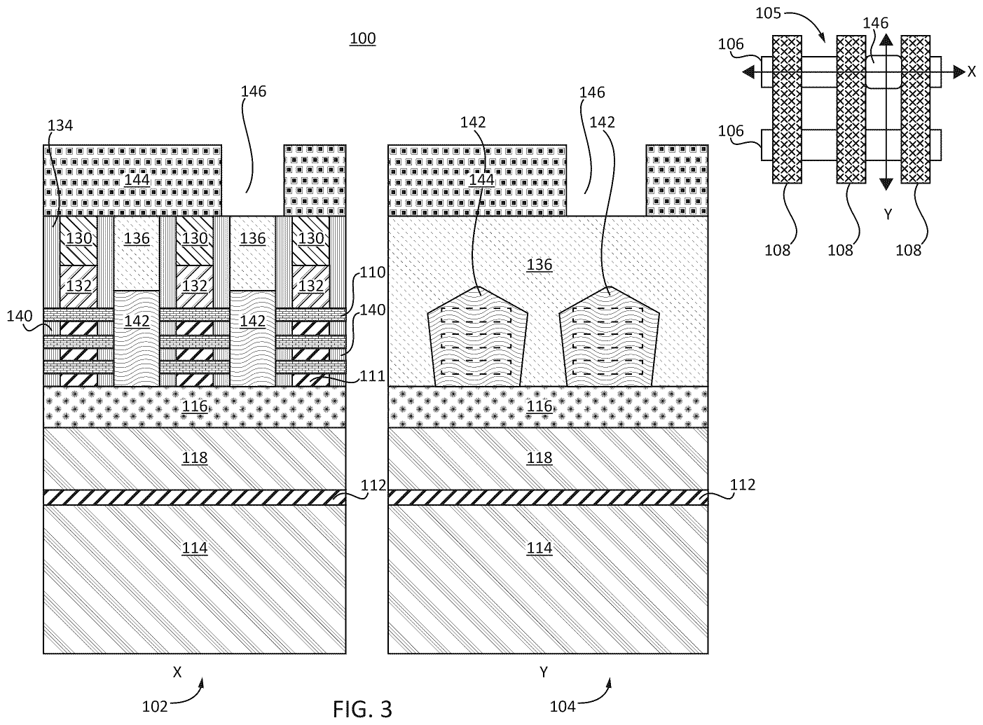

Referring to FIG. 3, contact lithography is performed to make connections to the source/drain regions 142. An etch mask 144 is formed on the ILD 136 and patterned to open up holes 146 to expose the ILD 136. The holes 146 are aligned with the source/drain regions 142 where contacts will be formed. In an embodiment, the etch mask 144 can include an organic planarizing layer (OPL), although other etch mask materials can be employed.

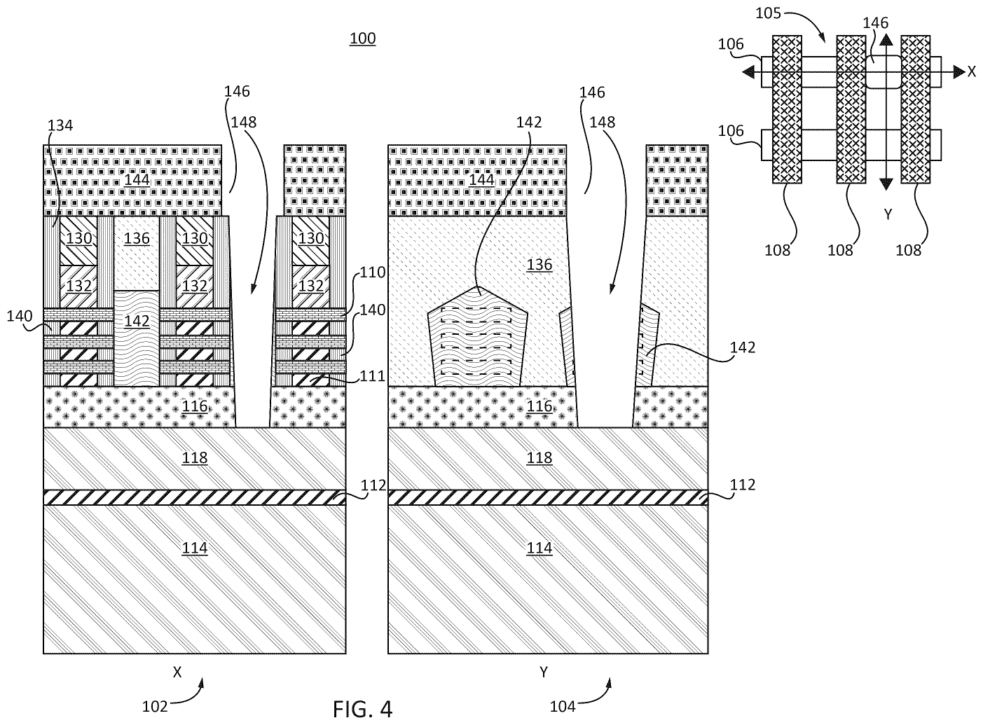

Referring to FIG. 4, contact openings 148 are formed through the holes 146 and extend through the ILD 136, the source/drain regions 142 and dielectric layer 116 to expose the semiconductor layer 118. The contact openings 148 can be formed using an anisotropic etch process, such as reactive ion etching (RIE) although other etch processes can be employed, e.g., ion beam etching (IBE). The contact openings 148 expose unetched portions of the source/drain region 142 and the semiconductor layer 118.

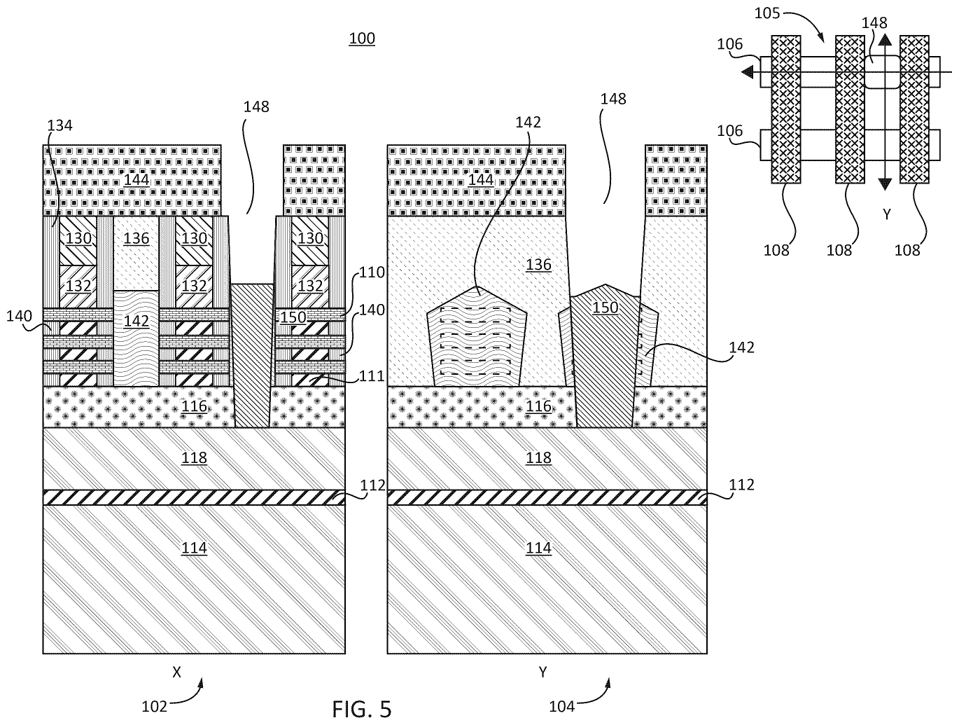

Referring to FIG. 5, a portion 150 of the source/drain region 142 is regrown and extends through the dielectric layer 116 and contacts the semiconductor layer 118. The portion 150 extends below gate structures where dummy gates 132 are formed. The portion 150 is regrown using an epitaxial growth process. For example, epitaxy can be done by ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), molecular beam epitaxy (MBE). Epitaxial materials may be grown from gaseous or liquid precursors. Epitaxial materials may be grown using vapor-phase epitaxy (VPE), molecular-beam epitaxy (MBE), liquid-phase epitaxy (LPE), or other suitable processes. Epitaxial silicon, silicon germanium (SiGe), and/or carbon doped silicon (Si:C) silicon can be doped during deposition (in-situ doped) by adding dopants, N-type dopants (e.g., P or As) or P-type dopants (e.g., B or Ga), depending on the type of transistor.

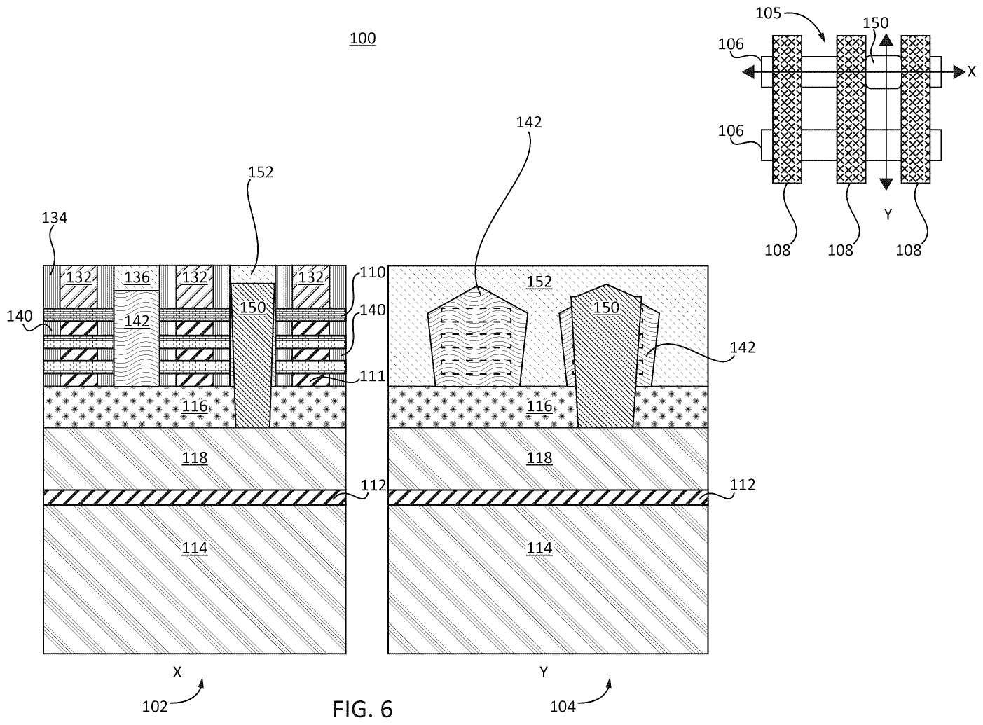

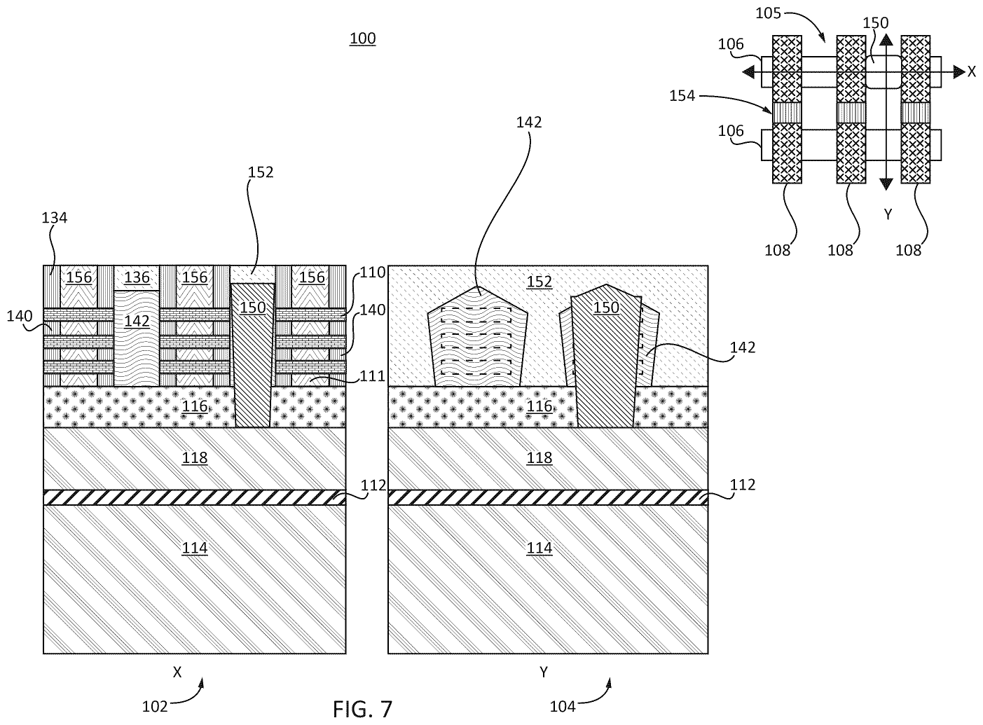

Referring to FIG. 6, the ILD 136 is extended by depositing materials 152 over the wafer 100 to fill in the opening 148 over the portion 150 of the source/drain region 142. The ILD 136 can include any suitable material and can include a same material as or different material than the ILD 136. A free surface of the wafer 100 is planarized, e.g., by a chemical mechanical polish (CMP) process. A gate cut 154 can be formed by a lithographical pattern and etch to cut the gate lines as depicted in the inset layout view 105 of FIG. 7.

Referring to FIG. 7, the dummy gates 132 and the semiconductor layers 111 are removed by a wet or dry etch. A gate dielectric layer (not shown) is deposited to cover the transistor channels 110. The gate dielectric layer can be formed by, e.g., CVD or ALD. Suitable examples of oxides that can be employed for the gate dielectric layer can include, but are not limited to: Al₂O₃, ZrO₂, HfO₂, Ta₂O₃, TiO₂ and combinations thereof.

A gate conductive material is formed over the gate dielectric layer and fills spaces between the transistor channels 110 in a replacement metal gate (RMG) process. The gate conductive material can include at least one gate conductor. The gate conductive material can include any conductive metal including, but not limited to W, Ni, Ti, Mo, Ta, Cu, Pt, Ag, Au, Ru, Ir, Rh, and Re, and alloys that include at least one of these conductive materials. The gate conductive material can include one or more layers of conductive materials. In one example, a second conductive material may be formed. When a combination of conductive elements is employed, an optional diffusion barrier material such as TaN or WN may be formed between the conductive materials. The gate conductive material can be deposited by CVD, plasma enhanced CVD (PECVD), ALD or other suitable deposition processes. With the deposition of the gate conductive material, gate conductors 156 are formed, which include high dielectric constant metal gates (HKMG).

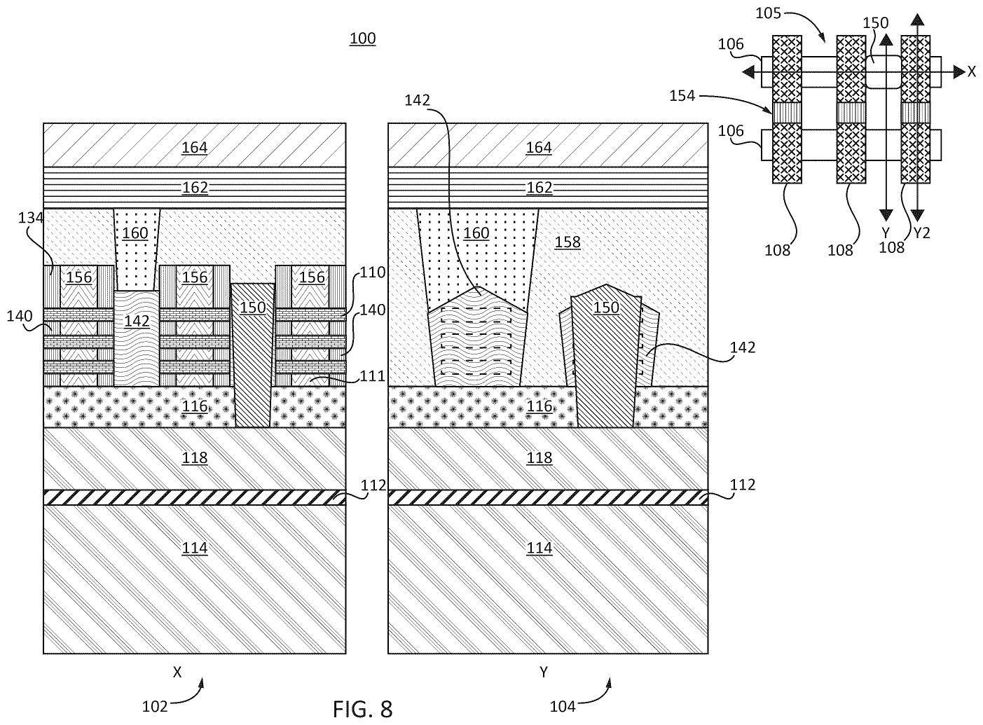

Referring to FIG. 8, a dielectric layer 158 is deposited over the wafer 100. The dielectric layer can include any suitable material and can include a same material as or different material than the ILD 136. A free surface of the wafer 100 is planarized, e.g., by a CMP process. Middle of the line (MOL) contacts are formed to make connections to selected source/drain regions 142 from a top side of the wafer 100. Trenches or holes are formed in the dielectric layer 158. The trenches or holes expose the underlying source/drain regions 142.

In some embodiments, a silicide liner, such as Ti, Ni, NiPt is deposited first, then a diffusion barrier can be formed in the trenches prior to a conductive fill. The diffusion barrier can include, e.g., TiN, TaN, or similar materials.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), atomic layer deposition (ALD) or any other suitable deposition method. The conductive fill is planarized, e.g., by CMP, to form contacts 160. The contacts 160 are formed to make connections to the source/drain regions 142 from a top or frontside of the wafer 100.

Processing continues with the formation of back end of line (BEOL) structures in a BEOL interconnect layer 162, which can include metal structures and dielectric layers to complete the top side of the wafer 100 being fabricated. A carrier wafer 164 can be bonded to the BEOL interconnect layer 162 by employing a bonding oxide or other adhesive. The carrier wafer 164 provides support and transportability to the wafer 100 for further processing which includes flipping the wafer 100 and removing portions of a bottom or backside.

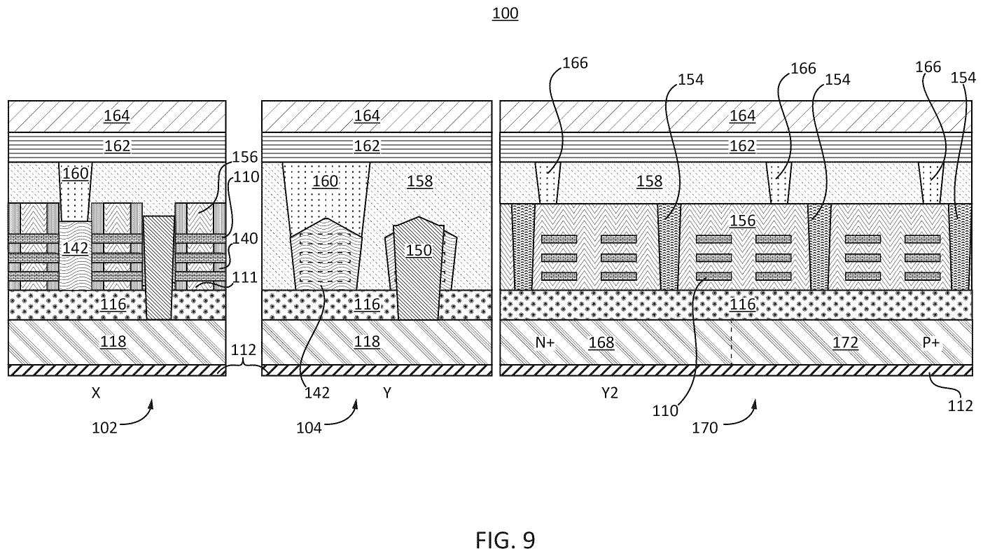

Referring to FIG. 9, to continue processing, the wafer 100 can be flipped to process features on the bottom or backside of the wafer 100. However, for clarity and consistency, the wafer 100 will be shown in the FIGS. in a same orientation as previously described with continued and consistent reference to bottom/top. An additional view 170 is depicted in FIG. 9 that shows a cross-sectional view taken at section line Y2 in the inset layout view 105 of FIG. 8. The additional view 170 shows gate contacts 166 and gate cuts 154 between gate conductors 156.

The semiconductor layer 118 includes doped portions 168 and 172. The doping of doped portions 168 and 172 can be pre-existing, provided upon formation of the semiconductor layer 118, e.g., by epitaxial growth, or can be doped by implantation methods. The doped portions 168 and 172 include dopants of opposite conductivity. For example, doped portion 168 can include N-type dopants with high concentration (N+) and doped portion 172 can include P-type dopants with high concentration (P+) (or vice versa). The substrate 114 is removed from the backside of the wafer 100. The substrate 114 can be removed by an etch process that stops on the etch stop layer 112.

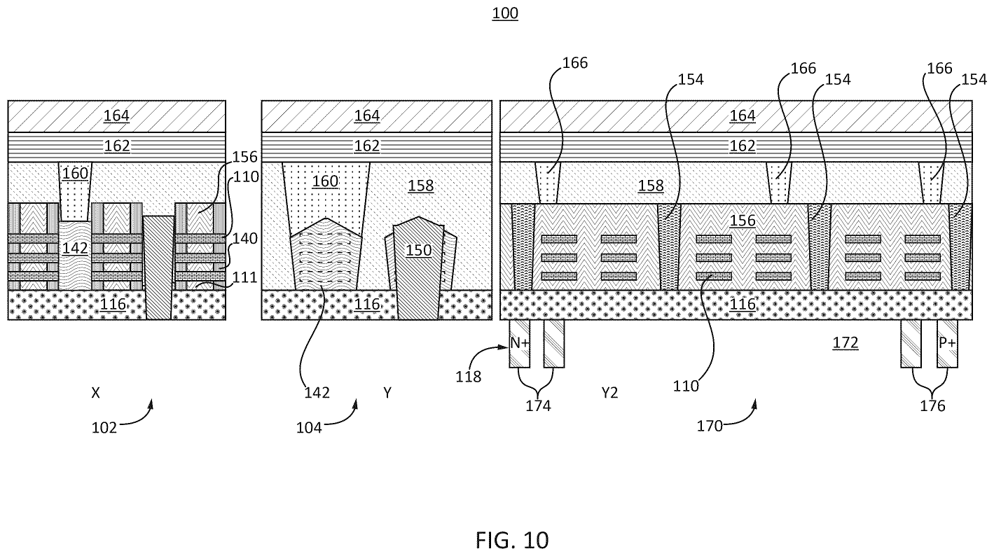

Referring to FIG. 10, the etch stop layer 112 is removed by an etch process. In an alternate embodiment, a CMP process can be employed. With the removal of the etch stop layer 112, the semiconductor layer 118 is exposed. The semiconductor layer 118 is patterned using lithography and an etch process that removes material of the semiconductor layer 118 relative to the dielectric layer 116. The etch process to remove portions of the semiconductor layer 118 can include RIE or IBE. The etch process forms pillars 174 and 176. Pillars 174 are of a first dopant type (e.g., N) while pillars 176 are of a second dopant type (e.g., P). The pillars 174 and 176 get there dopant properties based upon the doped portions 168 and 172 from which they are formed. The pillars 174 and 176 include monocrystalline or predominantly monocrystalline material which can be employed in forming a thermoelectric cooling device in later steps.

It should be understood that while doped portions 168 and 172 are depicted for formation of pillars 174 and 176, pillars 174 and 176 can be formed from any material that can induce the thermoelectric effect, e.g., N- and P-type semiconductors, semiconductive alloys, topological materials, etc. can be deposited and patterned for use as pillars 174 and 176. In some embodiments, the pillars 174 and 176 can be formed from materials, such as, e.g., Sb₂Te₃, PbTe, CeFe₄Sb₁₂, Bi₂Te₃, CoSb₃, La₃Te₄, SiGe alloys of these materials and combinations of these compounds and/or elements can also be employed.

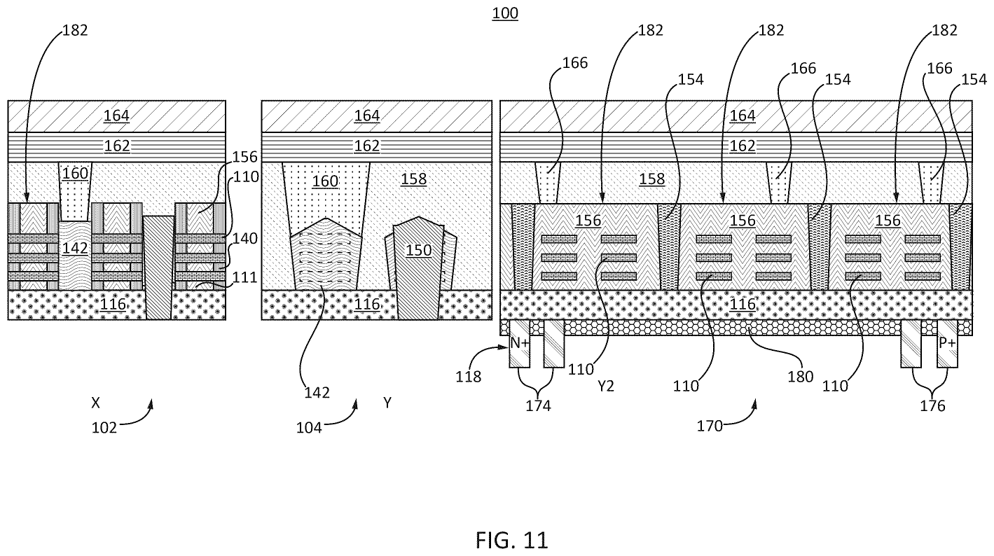

Referring to FIG. 11, a deposition process is performed to apply a conductive material over the pillars 174 and 176 and on the dielectric layer 116. The conductive material can include, e.g., Cu, Ru, Mo, Rh, W, Ir, and alloys or combinations of these and other conductive materials. In a particularly useful embodiment, the conductive fill includes Cu or other metal with a high conductivity. The conductive material can be formed using a deposition method, such as, e.g., CVD, PECVD, ALD or any other suitable deposition method. The conductive material is recessed to expose the pillars 174 and 176 and to define a thickness of the conductive material. The conductive material is then patterned to define a cooling plate 180 to be employed for a thermoelectric cooling device.

Transistor channels 110 can generate a significant amount of heat. Since conductive bodies, such as contacts, and other metal structures have a low density on a backside of the wafer 100, it becomes difficult to dissipate this heat. Therefore, placement of the cooling plate 180 at or near the backside of the wafer 100 in an area around the transistor channels 110 can improve device function. However, it should be understood that while FIG. 11 depicts the cooling plate 180 to be located below gate structures 182, the cooling plate 180 can be formed at any location on the wafer 100 to provide heat dissipation from components on the wafer 100. By providing an active heat sink for components of the semiconductor device, a thermoelectric device solves heat dissipation issues and effectively enhances device performance by reducing thermal carrier transport limitations.

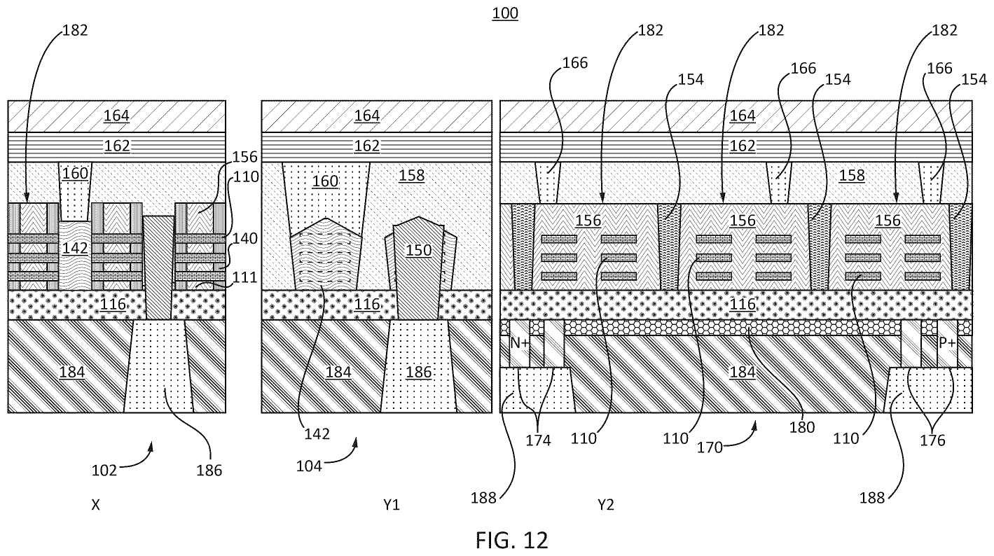

Referring to FIG. 12, a dielectric layer 184 is deposited over the backside of the wafer 100. The dielectric layer 184 is formed over the pillars 174 and 176, the dielectric layer 116 and the cooling plate 180. The dielectric layer 184 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H.

Openings are formed to expose pillars 174 and 176 and the portions 150 of the source/drain region 142 from the backside of the wafer 100. Openings can be patterned using lithography and etched in accordance with an etch mask by an anisotropic etch process, e.g., RIE.

A silicide liner (not shown), such as Ti, Ni, NiPt, then a diffusion barrier (not shown) can be formed in the openings prior to a conductive fill. The diffusion barrier can include, e.g., TiN, TaN, or similar materials. The conductive fill is performed to fill the openings and make electrical contact with the pillars 174 and 176 and the source/drain regions 142 (including the portion 150). The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form backside contacts 186 and backside contacts 188. The backside contacts 188 connect to the pillars 174 and 176.

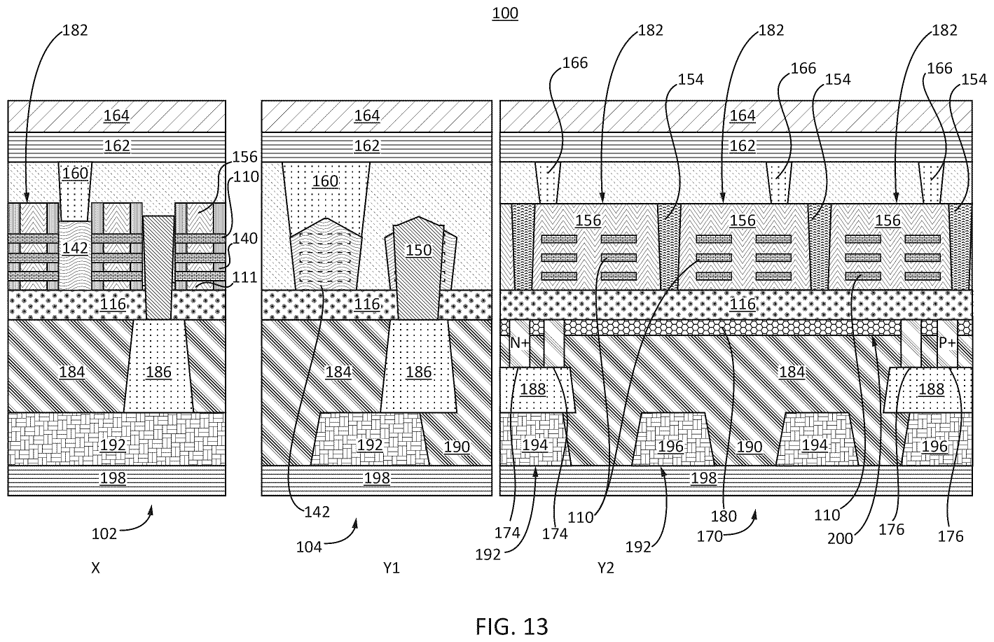

Referring to FIG. 13, additional dielectric materials are deposited to form dielectric layer 190. The dielectric layer 190 is patterned and backside power rails (BSPR) 192 are deposited and planarized. The dielectric layer 190 can include the materials and processes as described herein for other dielectric layers. The backside power rails 192 can include any suitable conductive materials, e.g., Cu, Ru, etc.

The backside power rails 192 contact the backside contacts 186 and backside contacts 188. The backside power rails 192 provide supply voltage power and can be employed in powering a thermoelectric device 200. Backside power rails 192 can alternate between positive supply voltage 194 (VDD) and negative supply voltage 196 (VSS or ground). The positive supply voltage 194 and negative supply voltage 196 connect to the backside contacts 188 to power the thermoelectric device 200.

In the embodiment shown in FIG. 13, the positive supply voltage 194 (VDD power) is wired to N+ pillars 174 through the backside contact 188, and the negative supply voltage 196 (VSS power) is wired to P+ pillars 176 through the backside contact 188. It should be understood that the number of pillars 174 or pillars 176 and their location can be varied and that the two pillars are shown for N-type pillars and two pillars are shown for P-type pillars for illustrative purposes.

A backside power distribution network (BSPDN) 198 is formed and includes dielectric layers and metallization structures that can connect components on the wafer 100. The BSPDN 198 connects to the thermoelectric device 200 through the backside power rails 192 and backside contacts 188. The BSPDN 198 also connects to source/drain regions 142 having the portion 150 that extends through the dielectric layer 116 and connects to the backside contacts 186 through the backside power rails 192.

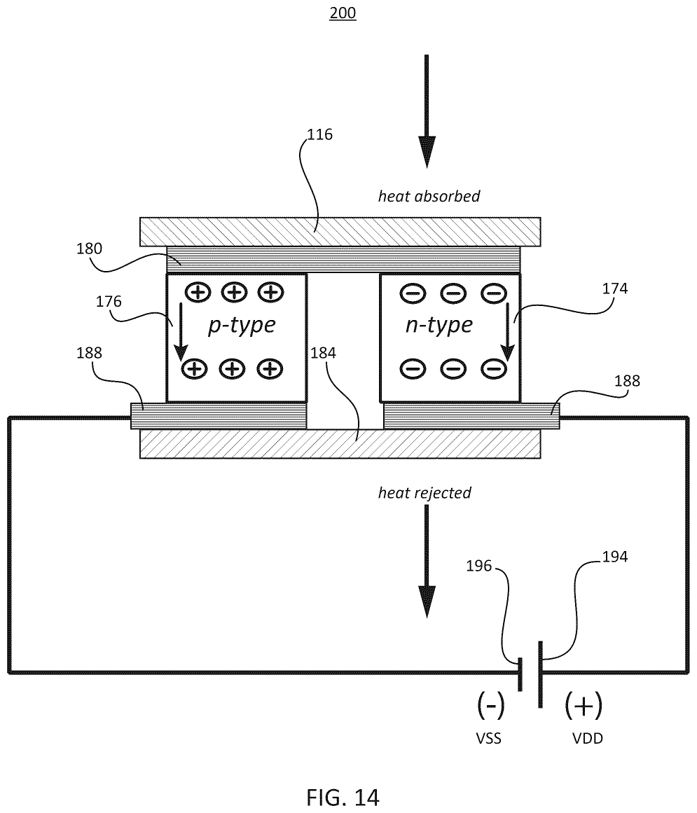

Referring to FIG. 14, a schematic diagram shows the operation of the thermoelectric device 200 in accordance with embodiments of the present invention. The thermoelectric device 200 employs one N-type semiconductor (e.g., pillars 174) and one P-type semiconductor (e.g., pillars 176) to provide different electron densities. Alternating P-type and N-type semiconductor pillars are provided thermally in parallel to each other and electrically in series. The cooling plate 180 joins one side of the pillars 174 and 176. When a voltage (e.g., VDD) is applied to ends of the two semiconductors (the pillars 174 and 176) there is a flow of DC current across the junction of the semiconductors, causing a temperature difference. A side with the cooling plate 180 absorbs heat which is then transported by the pillars 174 and 176 to the other side of the thermoelectric device 200. Cross-sectional areas of the pillars 174 and 176, and the lengths of the pillars 174 and 176 have an impact on the ability to transfer heat.

The thermoelectric device 200 can employ the Peltier effect to draw energy away from hot spots on a semiconductor device. In an embodiment, a power connection for the thermoelectric device 200 can be controlled by a field effect transistor (FET), e.g., a FET connected on a backside of the wafer 100 (e.g., a FET including portion 150). In other embodiments, the thermoelectric device 200 can always be connected to draw away heat from components on semiconductor devices formed from the wafer 100.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
transistor devices disposed on a frontside of a dielectric layer;
a thermoelectric device having a cooling plate disposed on a backside of the dielectric layer; and
the thermoelectric device including pillars connected to backside power rails by backside contacts.

2. The semiconductor device as recited in claim 1, wherein the cooling plate spans an area occupied by the transistor devices.

3. The semiconductor device as recited in claim 1, wherein the pillars are partially embedded within the cooling plate.

4. The semiconductor device as recited in claim 1, wherein the backside power rails provide supply voltages to the thermoelectric device.

5. The semiconductor device as recited in claim 1, wherein the transistor devices include a field effect transistor having a source/drain region that extends through the dielectric layer.

6. The semiconductor device as recited in claim 5, wherein the source/drain region connects to the backside power rails by the backside contacts.

7. The semiconductor device as recited in claim 1, wherein the pillars include monocrystalline semiconductor material.

8. The semiconductor device as recited in claim 1, wherein the pillars include a topological material.

9. A semiconductor device, comprising:
a dielectric layer;
a component disposed on the dielectric layer;
a first doped pillar disposed on the dielectric layer on a side opposite the component;
a second doped pillar disposed on the side opposite the component and apart from the first doped pillar;
a cooling plate electrically connected to the first doped pillar and the second doped pillar to provide a thermoelectric device;
contacts connected to each of the first doped pillar and the second doped pillar; and
power rails connected to the contacts.

10. The semiconductor device as recited in claim 9, wherein the cooling plate spans an area occupied by the component.

11. The semiconductor device as recited in claim 10, wherein the first doped pillar and the second doped pillar are partially embedded within the cooling plate.

12. The semiconductor device as recited in claim 9, wherein the power rails are disposed on a backside of the semiconductor device.

13. The semiconductor device as recited in claim 9, wherein the component includes a field effect transistor and the field effect transistor includes a source/drain region that extends through the dielectric layer.

14. The semiconductor device as recited in claim 13, wherein the source/drain region connects to the power rails by the contacts.

15. The semiconductor device as recited in claim 9, wherein the first doped pillar and the second doped pillar are monocrystalline.

16. A semiconductor device, comprising:
field effect transistors disposed on a dielectric layer;
a cooling plate disposed on the dielectric layer on a side opposite the field effect transistors;
an N-type monocrystalline pillar partially embedded within the cooling plate;
a P-type monocrystalline pillar partially embedded within the cooling plate;
a first contact connected to the N-type monocrystalline pillar;
a second contact connected to the P-type monocrystalline pillar;
a backside positive supply power rail connected to the first contact; and
a backside negative supply power rail connected to the second contact.

17. The semiconductor device as recited in claim 16, wherein the cooling plate spans an area occupied by the field effect transistors.

18. The semiconductor device as recited in claim 16, wherein a field effect transistor includes a source/drain region that extends through the dielectric layer.

19. The semiconductor device as recited in claim 18, wherein the source/drain region includes a backside connection.

20. The semiconductor device as recited in claim 16, wherein the cooling plate includes a metal.
